(19) United States
(12) Patent Application Publication
(10) Pub. No.: US 2014/0166084 A1
(43) Pub. Date: Jun. 19, 2014

(54) SOLAR CELL AND MANUFACTURING METHOD OF THE SAME

(71) Applicant: Myung Seok Shim, Seoul (KR)

(72) Inventor: Myung Seok Shim, Seoul (KR)

(73) Assignee: LG INNOTEK CO., LTD., Seoul (KR)

(21) Appl. No.: 14/235,965

(22) PCT Filed: Jul. 18, 2012
(86) PCT No.: PCT/KR2012/005717

§ 371 Date: Jan. 29, 2014

(30) Foreign Application Priority Data
Jul. 29, 2011 (KR) 10-2011-0076281

(51) Int. Cl. H01L 31/0216; H01L 31/0224; H01L 31/18

(52) U.S. Cl. CPC H01L 31/02167; H01L 31/18; H01L 31/022425
USPC 136/252; 438/98

(57) ABSTRACT

Disclosed is a solar cell including a substrate, a back electrode layer on the substrate, a light absorbing layer on the back electrode layer, a transparent electrode layer on the light absorbing layer, and an impurity diffusion preventing layer between the substrate and the back electrode layer. The impurity diffusion preventing layer is formed on the substrate, so that the impurities come from the substrate during the high-temperature process are prevented from being diffused to the back electrode layer and the light absorbing layer.

### TECHNICAL FIELD

The disclosure relates to a solar cell. In more particular, the disclosure relates to a solar cell capable of improving the efficiency of the solar cell and a method of fabricating the same.

### BACKGROUND ART

In general, a solar cell converts solar energy into electrical energy. The solar cell has been extensively used for the commercial purpose as energy consumption is increased recently.

The solar cell is fabricated by laminating a back electrode layer, a light absorbing layer, and a transparent electrode layer on a transparent glass substrate and electrically connecting the back electrode layer to the transparent electrode layer.

However, according to the solar cell of the related art, a deposition layer is formed through a high-temperature process. Accordingly, impurities are discharged from the glass substrate during the high-temperature process, and the impurities are infiltrated into the back electrode layer or the light absorbing layer.

Therefore, efficiency and reliability may be degraded due to the increase of the resistance of the back electrode layer and the contamination of the light absorbing layer.

### DISCLOSURE OF INVENTION

### Technical Problem

In order to solve the above problem, there is provided a solar cell capable of preventing impurities, which come from the substrate, from being diffused and a method of fabricating the same.

### Solution to Problem

In order to accomplish the above object, there is provided a solar cell including a substrate, a back electrode layer on the substrate, a light absorbing layer on the back electrode layer, a transparent electrode layer on the light absorbing layer, and an impurity diffusion preventing layer between the substrate and the back electrode layer.

In addition, according to the embodiment, there is provided a method of fabricating a solar cell. The method includes preparing a substrate, forming an impurity diffusion preventing layer on the substrate, forming a back electrode layer on the impurity diffusion preventing layer, forming a light absorbing layer on the back electrode layer, and forming a transparent electrode layer on the light absorbing layer.

### Advantageous Effects of Invention

According to the disclosure, the impurity diffusion preventing layer is formed on the substrate, so that the impurities come from the substrate at a high temperature can be prevented from being diffused into the back electrode layer and the light absorbing layer.

In addition, according to the disclosure, the adhesive diffusion layer is formed on the impurity diffusion preventing layer to improve the adhesive strength with the back electrode layer, so that the reliability of the solar cell can be improved.

In addition, according to the disclosure, the adhesive strength is formed by using silicon oxide, so that the material constituting the back electrode layer can be freely selected.

### BRIEF DESCRIPTION OF DRAWINGS

FIG. 1 is a sectional view showing a solar cell according to the disclosure; and

FIGS. 2 to 10 are sectional views showing a method of fabricating a solar cell according to the disclosure.

### MODE FOR THE INVENTION

Hereinafter, the embodiment of the disclosure will be described with reference to accompanying drawings.

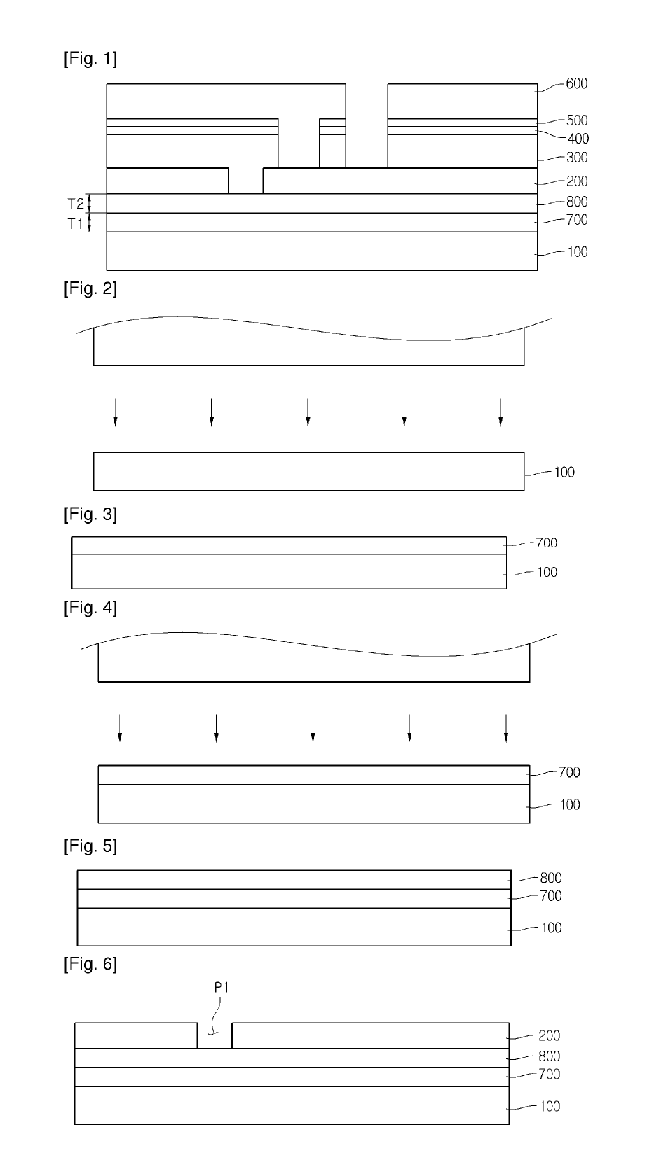

FIG. 1 is a sectional view showing a solar cell according to the disclosure.

Referring to FIG. 1, the solar cell according to the disclosure includes a substrate 100, a back electrode layer 200 formed on the substrate 100, a light absorbing layer 300 formed on the back electrode layer 200, first and second buffer layers 400 and 500 formed on the light absorbing layer 300, a transparent electrode layer 600 formed on the second buffer layer 500, an impurity diffusion preventing layer 700 interposed between the substrate 100 and the back electrode layer 200, and an adhesive strength improving layer 800.

The substrate 100 may have a plate shape, and may include a transparent glass material.

The substrate 100 may be rigid or flexible. The substrate 100 may include a plastic substrate or a metallic substrate in addition to the glass substrate. In addition, the substrate 100 may include a soda lime glass containing sodium.

The impurity diffusion preventing layer 700 according to the disclosure may be formed on the substrate 100.

The impurity diffusion preventing layer 700 prevents impurities come from the substrate 100 in the high-temperature process from being infiltrated into the back electrode layer 200 and the light absorbing layer 300.

The adhesive strength improving layer 800 may be additionally formed on the impurity diffusion preventing layer 700.

The adhesive strength improving layer 800 improves the adhesive strength between the impurity diffusion preventing layer 700 and the back electrode layer 200.

In other words, if the stress index of the impurity diffusion preventing layer 700 is increased, the adhesive strength between the impurity diffusion preventing layer 700 and the back electrode layer 200 may be weakened due to the difference in stress between the impurity diffusion preventing layer 700 and the back electrode layer 200.

Therefore, the adhesive strength between the impurity diffusion preventing layer 700 and the back electrode layer 200 can be prevented from being degraded by additionally forming the adhesive strength improving layer 800.

Hereinafter, the impurity diffusion preventing layer 700 and the adhesive strength improving layer 800 according to the disclosure will be described in detail.

The back electrode layer 200 may be formed on the adhesive strength improving layer 800.

The back electrode layer 200 may include molybdenum (Mo). The back electrode layer 200 may include metal such as aluminum (Al), nickel (Ni), chrome (Cr), titanium (Ti), silver (Ag), or gold (Au), or ITO, ZnO, or SnO2 constituting the transparent conductive layer (TCO) in addition to Mo.

The back electrode 200 may include at least two layers by using homogeneous metal or heterogeneous metal.

The light absorbing layer 300 may be formed on the back electrode layer 200.

The light absorbing layer 300 includes a group I-III-VI compound. For example, the light absorbing layer 300 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure.

The first buffer layer 400 may be formed on the light absorbing layer 300.

The first buffer layer 400 is formed on the light absorbing layer 300 while directly making contact with the light absorbing layer 300, and reduces the energy gap difference between the light absorbing layer 300 and the transparent electrode layer 600 that will be described later.

The first buffer layer 400 may include CdS, and the energy bandgap of the first buffer layer 400 may have an intermediate value between the energy bandgap of the back electrode layer 200 and the energy bandgap of the transparent electrode layer 600.

The second buffer layer 500 may be formed on the first buffer layer 400.

The second buffer layer 500 serves as a high resistance buffer layer and may include zinc oxide (ZnO) representing high light transmittance and high electrical conductivity.

The second buffer layer 500 can prevent the insulation from the transparent electrode layer 600 and prevent damage caused by the impact.

The transparent electrode layer 600 may be formed on the second buffer layer 500.

The transparent electrode layer 600 may include a transparent conductive material, and may include Al doped zinc oxide (AZO; ZnO:Al).

The transparent electrode layer 600 may include one of zinc oxide (ZnO), tin oxide (SnO₂), and indium tin oxide (ITO) representing high light transmittance and high electrical conductivity in addition to AZO.

Meanwhile, the impurity diffusion preventing layer 700 according to the disclosure is directly formed on the substrate 100, and may have a predetermined thickness of 2 μm or less.

The impurity diffusion preventing layer 700 may include a material including silicon nitride (SiNx).

Since the silicon nitride is non-oxide ceramic and has superior thermal characteristics and mechanical characteristics, the silicon nitride represents superior characteristics to prevent the infiltration of impurities come from the substrate 100 in the high temperature process.

Although the impurity diffusion preventing layer 700 is formed at a thickness of 2 μm or less, the embodiment is not limited thereto, and the thickness of the impurity diffusion preventing layer 700 can be desirably adjusted according to the impurity diffusion concentration of the substrate 100.

Although the impurity diffusion preventing layer 700 is formed on the entire surface of the substrate 100, the embodiment is not limited thereto, and the impurity diffusion preventing layer 700 may be formed only on a predetermined region of the substrate 100.

The impurity diffusion preventing layer 700 prevents the impurities come from the substrate 100 during the high temperature process from being diffused, thereby preventing efficiency and reliability from being degraded due to the increase of the resistance of the back electrode layer 200 and the contamination of the light absorbing layer 300.

Meanwhile, since the silicon nitride-based material constituting the impurity diffusion preventing layer 700 represents a great stress index, the adhesive strength between the impurity diffusion preventing layer 700 and the back electrode layer 200 may be weakened. Accordingly, limitation exists when the material constituting the back electrode layer 200 is selected.

Therefore, the adhesive strength improving layer 800 may be additionally formed on the impurity diffusion preventing layer 700 in order to improve the adhesive strength with the back electrode layer 200.

The adhesive strength improving layer 800 may be formed on the impurity diffusion preventing layer 700 through a deposition process.

The adhesive strength improving layer 800 may include a silicon oxide (SiO2) and may have a thickness T2 of 2 μm or less.

The adhesive strength improving layer 800 includes a material representing a stable chemical bonding material and representing superior adhesive strength with the back electrode layer 200. The adhesive strength improving layer 800 allows the easy selection of the material constituting the back electrode layer 200, and increases the selection range of the material of the back electrode layer 200.

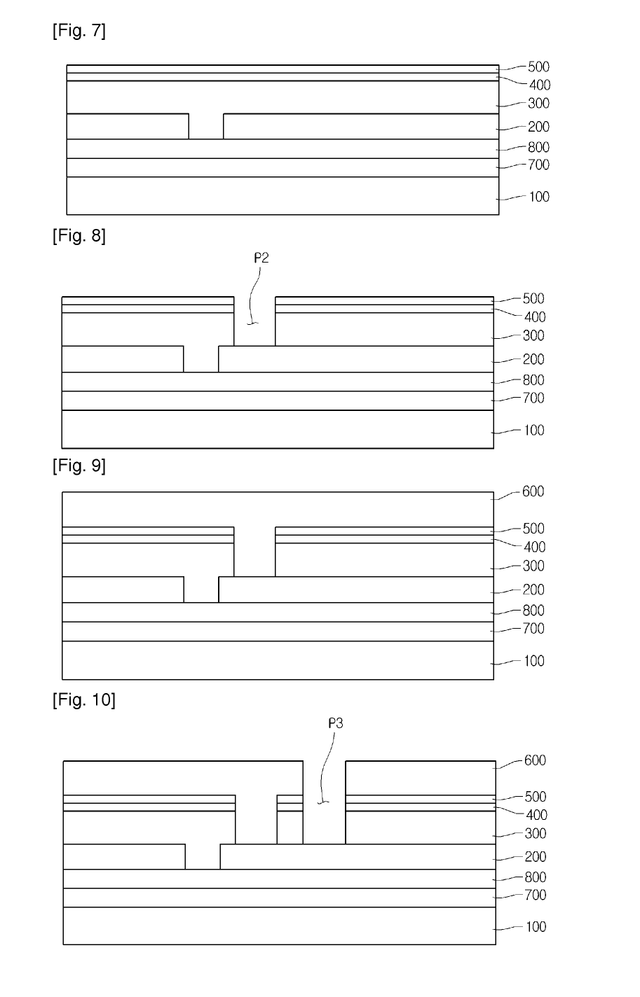

Hereinafter, the method of fabricating the solar cell according to the disclosure will be described with reference to accompanying drawings. FIGS. 2 to 10 are sectional views showing the method of fabricating the solar cell according to the disclosure.

As shown in FIG. 2, if the substrate 100 is prepared, the impurity diffusion preventing layer 700 is performed on the substrate 100.

The impurity diffusion preventing layer 700 may include a silicon nitride-based material. The impurity diffusion preventing layer 700 may be formed as shown in FIG. 3 through a chemical deposition scheme, a sputtering scheme or an evaporation scheme.

As shown in FIG. 4, if the impurity diffusion preventing layer 700 is formed on the substrate 100, the adhesive strength improving layer 800 may be deposited on the impurity diffusion preventing layer 700.

The adhesive strength improving layer 800 may include a material such as a silicon oxide. The adhesive strength improving layer 800 may be formed as shown in FIG. 5 through a chemical deposition scheme, a sputtering scheme or an evaporation scheme.

As shown in FIG. 6, if the adhesive strength improving layer 800 is formed on the impurity diffusion preventing layer 700, the back electrode layer 200 is formed on the adhesive strength improving layer 800.

The back electrode layer 200 may be formed by depositing Mo through a sputtering scheme.

Thereafter, a patterning process may be formed to divide the back electrode layer 200 in the form of a strip, thereby forming a first pattern line P1. In this case, the patterning process may be performed by using a laser.

As shown in FIG. 7, if the first pattern line P1 is formed on the back electrode layer 200, the light absorbing layer 300, the first buffer layer 400, and the second buffer layer 500 are sequentially formed on the back electrode layer 200.

The light absorbing layer 300 may be formed through the co-deposition scheme using CIGS.

The first buffer layer 400 may be formed by depositing CdS through a chemical bath deposition scheme (CBD).

The second buffer layer 500 may be formed by depositing ZnO through a sputtering process.

As shown in FIG. 8, if the light absorbing layer 300, the first buffer layer 400, and the second buffer layer 500 are sequentially laminated on the back electrode layer 200, a second pattern line P2 may be formed at portions of the light absorbing layer 300, the first buffer layer 400, and the second buffer layer 500 through the patterning process.

The second pattern line P2 may be spaced apart from the first pattern line P1 by a predetermined distance, and may be formed through a scribing scheme or by using a laser.

As shown in FIG. 9, if the second pattern line P2 is formed on the light absorbing layer 300, the first buffer layer 400, and the second buffer layer 500, the transparent electrode layer 600 is formed on the second buffer layer 500.

The transparent electrode layer 600 may be formed by depositing AZO through the sputtering scheme.

As shown in FIG. 10, if the transparent electrode layer 600 is formed on the second buffer layer 500, a third pattern line P3 may be formed on the light absorbing layer 300, the first buffer layer 400, the second buffer layer 500, and the transparent electrode layer 600.

The third pattern line P3 may be spaced apart from the second pattern line P2 by a predetermined distance, and may be formed through a scribing scheme or by using a laser.

Accordingly, the solar cell according to the disclosure can be completely fabricated.

Although an exemplary embodiment of the disclosure has been described for illustrative purposes, those skilled in the art will appreciate that various modifications, additions and substitutions are possible, without departing from the scope and spirit of the invention as disclosed in the accompanying claims.

1. A solar cell comprising:
a substrate;
a back electrode layer on the substrate;
a light absorbing layer on the back electrode layer;
a transparent electrode layer on the light absorbing layer; and
an impurity diffusion preventing layer between the substrate and the back electrode layer.

2. The solar cell of claim 1, wherein the impurity diffusion preventing layer includes a silicon nitride (SiNx).

3. The solar cell of claim 1, wherein the impurity diffusion preventing layer has a thickness of 0.5 μm to 2.0 μm.

4. The solar cell of claim 1, further comprising an adhesive strength improving layer between the impurity diffusion preventing layer and the back electrode layer.

5. The solar cell of claim 4, wherein the adhesive strength improving layer includes SiO₂.

6. The solar cell of claim 4, wherein the adhesive strength improving layer has a thickness in a range of about 0.5 μm to about 2.0 μm.

7. A method of fabricating a solar cell, the method comprising:
preparing a substrate;
forming an impurity diffusion preventing layer on the substrate;
forming a back electrode layer on the impurity diffusion preventing layer;
forming a light absorbing layer on the back electrode layer; and
forming a transparent electrode layer on the light absorbing layer.

8. The method of claim 7, wherein the impurity diffusion preventing layer is formed by depositing SiNₓ.

9. The method of claim 8, wherein the impurity diffusion preventing layer has a thickness in a range of 0.5 μm to 2.0 μm.

10. The method of claim 7, further comprising forming an adhesive strength improving layer on the impurity diffusion preventing layer after forming the impurity diffusion preventing layer.

11. The method of claim 10, wherein the adhesive strength improving layer is formed by depositing SiO₂.

12. The method of claim 10, wherein the adhesive strength improving layer has a thickness in a range of 0.5 μm to 2.0 μm.
